(19) United States
(12) Patent Application Publication
(10) Pub. No.: US 2025/0105068 A1
(43) Pub. Date: Mar. 27, 2025

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Chuan-Shun LI, Taichung City (TW); Pin-Jing SU, Taichung City (TW); Liang-Yi HUNG, Taichung City (TW); Chia-Cheng CHEN, Taichung City (TW); Yu-Po WANG, Taichung City (TW)

(21) Appl. No.: 18/762,383

(22) Filed: Jul. 2, 2024

(30) Foreign Application Priority Data
Sep. 27, 2023 (TW) 112137141

(51) Int. Cl. H01L 23/04; H01L 21/50; H01L 23/00; H01L 23/42

(52) U.S. Cl. CPC H01L 23/04; H01L 21/50; H01L 23/42; H01L 24/16; H01L 24/32; H01L 24/73; H01L 2224/16225; H01L 2224/32225; H01L 2224/73204; H01L 2924/16151

(57) ABSTRACT

An electronic package and a manufacturing method thereof are provided, in which a first barrier body and a second barrier body are disposed respectively, and a heat dissipation structure is formed with a hole thereon. Thereby, gas in the heat dissipation structure can be discharged via the hole, so as to prevent the gas from remaining in a thermal conductive layer and affecting the heat dissipation effect.

### CROSS-REFERENCE TO RELATED APPLICATIONS

The present application is based upon and claims the right of priority to TW Patent Application No. 112137141, filed Sep. 27, 2023, the disclosure of which is hereby incorporated by reference herein in its entirety for all purposes.

### BACKGROUND

### 1. Technical Field

The present disclosure relates to a package structure, and more particularly, to an electronic package with a heat dissipation structure and a manufacturing method thereof.

### 2. Description of Related Art

As the requirement for functionality and processing speed of electronic products increases, semiconductor chips, which are the core components of electronic products, need to have higher density of the electronic elements and electronic circuits. Therefore, the semiconductor chip will generate greater amounts of heat during operation. Furthermore, the conventional encapsulant covering the semiconductor chip is made of a poor heat transfer material with a thermal conductivity of only 0.8 W/mk. If the heat generated by the semiconductor chip cannot be effectively dissipated, it will cause damage to the semiconductor chip and the problem of product reliability.

In order to quickly dissipate the heat energy generated by the semiconductor chip to the outside, a heat dissipation member (heat sink or heat spreader) is usually configured in the semiconductor package in industry. The heat dissipation member is mainly bonded to the inactive surface of the semiconductor chip via a thermal interface material (TIM) layer, and the top sheet of the heat dissipation member is exposed from the encapsulant or directly to the atmosphere, thereby dissipating the heat generated by the semiconductor chip via the TIM layer and the heat dissipation member.

In a manufacturing method of a conventional semiconductor package 1, as shown in FIG. 1A, a semiconductor chip 11 is first disposed on a packaging substrate 10 with an active surface 11a thereof in a flip-chip bonding manner (i.e., via conductive bumps 111 and an underfill 112), and a barrier body 15 and an adhesive layer 14 are then disposed on the packaging substrate 10, so that the barrier body 15 surrounds side surfaces of the semiconductor chip 11. Next, a thermal interface material (TIM) layer 12 is formed on the semiconductor chip 11, and the TIM layer 12 on the semiconductor chip 11 is surrounded by the barrier body 15.

Subsequently, as shown in FIG. 1B, a top sheet 131 of a heat dissipation member 13 is bonded onto an inactive surface 11b of the semiconductor chip 11 via the TIM layer 12, and supporting legs 132 of the heat dissipation member 13 are disposed on the packaging substrate 10 via the adhesive layer 14. Next, a packaging and molding operation is performed so that the semiconductor chip 11 and the heat dissipation member 13 are covered with an encapsulant (not shown), and the top sheet 131 of the heat dissipation member 13 is exposed from the encapsulant.

When the semiconductor package 1 is in operation, the heat energy generated by the semiconductor chip 11 is conducted to the top sheet 131 of the heat dissipation member 13 via the inactive surface 11b of the semiconductor chip 11 and the TIM layer 12, so that heat is dissipated to the outside of the semiconductor package 1.

However, in the conventional semiconductor package 1, the barrier body 15 is mostly made of polymer material, and heating is often required when capping the heat dissipation member 13, which may cause the gas generated by the barrier body 15 to enter the TIM layer 12, such that the TIM layer 12 contains bubbles b. When the TIM layer 12 contains the bubbles b, the contact area between the TIM layer 12 and the heat dissipation member 13 is reduced, thereby affecting the heat dissipation effect.

Therefore, there is a need for a solution that addresses the aforementioned shortcomings in the prior art.

### SUMMARY

In view of the aforementioned shortcomings of the prior art, the present disclosure provides an electronic package, which includes: a carrier structure; an electronic element disposed on the carrier structure; a first barrier body disposed on the carrier structure and surrounding side surfaces of the electronic element; a second barrier body disposed on the first barrier body and formed with an opening exposing the electronic element; a thermal conductive layer formed on the electronic element exposed from the opening of the second barrier body, wherein the thermal conductive layer is surrounded by the second barrier body; and a heat dissipation structure disposed on the second barrier body and the thermal conductive layer, wherein the thermal conductive layer is between the electronic element and the heat dissipation structure, and the heat dissipation structure has a hole in communication with the opening.

The present disclosure also provides a method of manufacturing an electronic package, the method includes: disposing an electronic element on a carrier structure; disposing a first barrier body on the carrier structure, wherein the first barrier body surrounds side surfaces of the electronic element; disposing a second barrier body on the first barrier body, wherein the second barrier body is formed with an opening exposing the electronic element; disposing a heat dissipation structure with a hole on the second barrier body, wherein the hole is in communication with the opening of the second barrier body; and forming a thermal conductive layer on the electronic element exposed from the opening of the second barrier body via the hole, wherein the thermal conductive layer is surrounded by the second barrier body.

In the aforementioned electronic package and method, the first barrier body is heated and cured before disposing the second barrier body.

In the aforementioned electronic package and method, the heat dissipation structure is disposed on the second barrier body when the second barrier body is in an uncured state.

In the aforementioned electronic package and method, the first barrier body and the second barrier body have an interface therebetween.

In the aforementioned electronic package and method, the first barrier body is higher than the electronic element, and the first barrier body and the second barrier body together surround the thermal conductive layer on the electronic element.

In the aforementioned electronic package and method, the first barrier body and the second barrier body are made of same material.

In the aforementioned electronic package and method, the present disclosure further includes forming a covering layer on the hole.

In the aforementioned electronic package and method, the thermal conductive layer is made of a liquid thermal conductive material.

As can be understood from the above, in the electronic package and manufacturing method thereof of the present disclosure, the first barrier body and the second barrier body are disposed respectively, and the heat dissipation structure is formed with a hole thereon, so that the gas in the heat dissipation structure can be discharged via the hole to prevent gas from remaining in the thermal conductive layer and affecting the heat dissipation effect.

### BRIEF DESCRIPTION OF THE DRAWINGS

FIG. 1A and FIG. 1B are schematic cross-sectional views illustrating a manufacturing method of a conventional heat dissipation type semiconductor package.

FIG. 2A, FIG. 2B, FIG. 2C-1 and FIG. 2D are schematic cross-sectional views illustrating a manufacturing method of an electronic package of the present disclosure.

FIG. 2C-2 is a schematic partial top view of FIG. 2C-1.

### DETAILED DESCRIPTION

Implementations of the present disclosure are described below by embodiments. Other advantages and technical effects of the present disclosure can be readily understood by one of ordinary skill in the art upon reading the disclosure of this specification.

It should be noted that the structures, ratios, sizes shown in the drawings appended to this specification are provided in conjunction with the disclosure of this specification in order to facilitate understanding by those skilled in the art. They are not meant, in any ways, to limit the implementations of the present disclosure, and therefore have no substantial technical meaning. Without influencing the effects created and objectives achieved by the present disclosure, any modifications, changes or adjustments to the structures, ratios, or sizes are construed as falling within the scope covered by the technical contents disclosed herein. Meanwhile, terms such as “on,” “above,” “upper,” “under,” “below,” “lower,” “a,” “one,” “first,” “second,” and the like, are for illustrative purposes, and are not meant to limit the scope implementable by the present disclosure. Any changes or adjustments made to the relative relationships, without substantially modifying the technical contents, are also to be construed as within the scope implementable by the present disclosure.

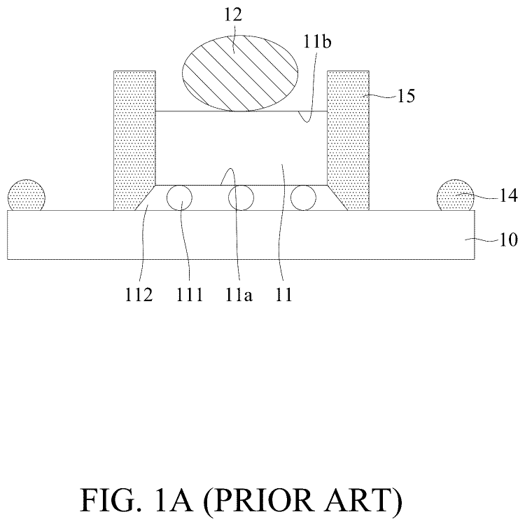

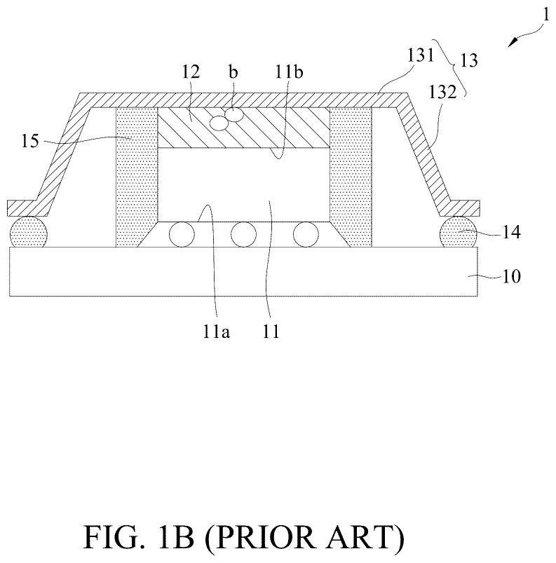

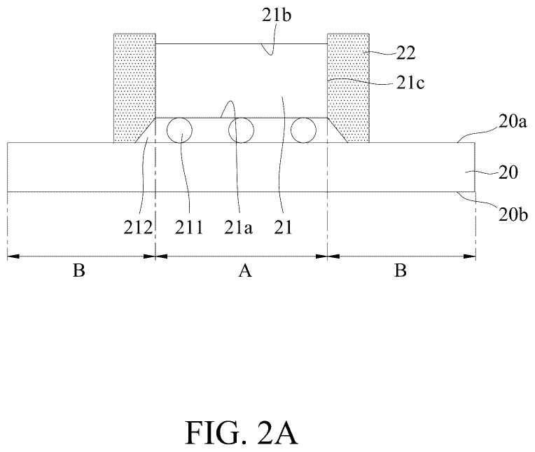

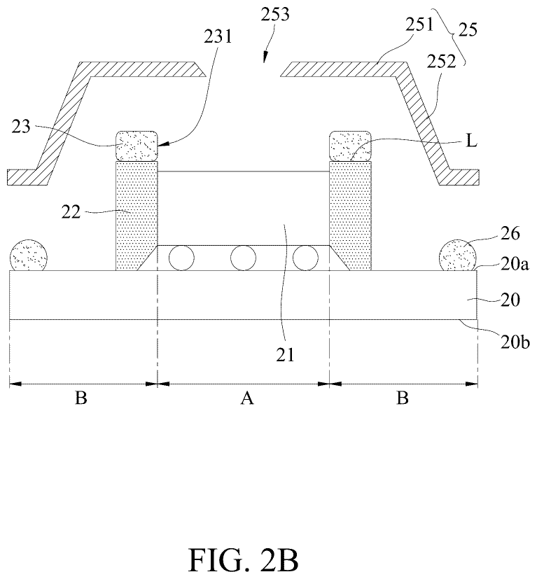

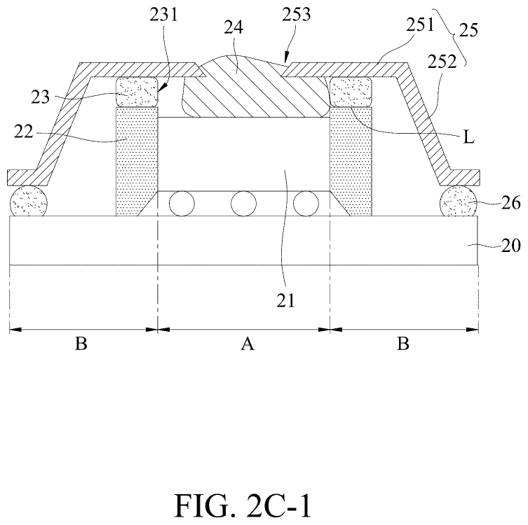

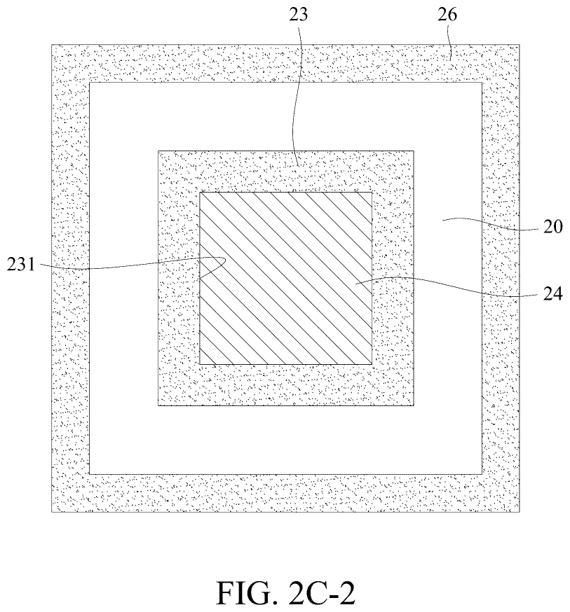

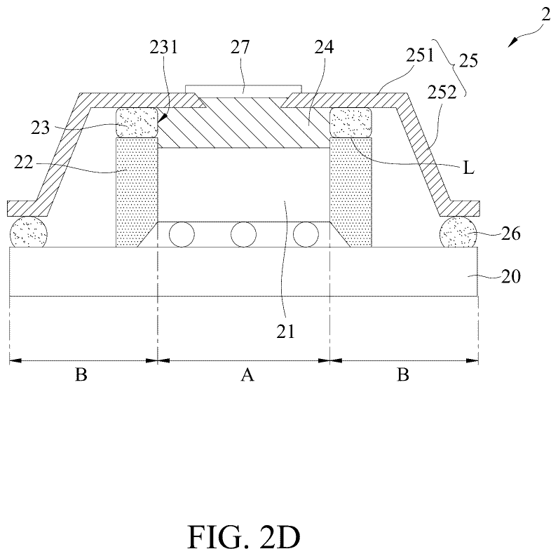

FIG. 2A, FIG. 2B, FIG. 2C-1 and FIG. 2D are schematic cross-sectional views illustrating a manufacturing method of an electronic package 2 of the present disclosure.

As shown in FIG. 2A, a carrier structure 20 having a first side 20a (e.g., upper side) and a second side 20b (e.g., lower side) opposing the first side 20a is provided, and at least one (or a plurality of) electronic element 21 is disposed on the first side 20a of the carrier structure 20. “At least one” used in the present disclosure represents one or more (such as one, two, three or more), and “plurality” represents two or more (such as two, three, five, ten or more).

In one embodiment, the carrier structure 20 may be a packaging substrate having a core layer and a circuit portion or a coreless circuit structure. The first side 20a of the carrier structure 20 can be used as a chip mounting side for carrying the electronic element 21, and the second side 20b of the carrier structure 20 can be served as a ball placement side for sequentially mounting solder balls (such as tin balls) and electronic devices (such as circuit boards).

It should be understood that the carrier structure 20 can also be other types of carrying unit for carrying the electronic element 21 (e.g., a chip) such as a lead frame, or the carrier structure 20 can be other types of board with metal routings, and the present disclosure is not limited to as such.

In one embodiment, the electronic element 21 may be an active element, a passive element, or a combination of the active element and the passive element. For example, the active element may be a semiconductor chip or the like.

In one embodiment, the electronic element 21 can be a semiconductor chip and has an active surface 21a and an inactive surface 21b opposing the active surface 21a, and the active surface 21a of the electronic element 21 can have a plurality of electrode pads (not shown), so that the plurality of electrode pads are bonded to and electrically connected to the circuit layer of the carrier structure 20 via a plurality of conductive bumps 211 made of such as solder material in a flip-chip manner, and then an encapsulating layer such as an underfill 212 is filled and formed between the first side 20a of the carrier structure 20 and the active surface 21a of the electronic element 21 to cover the plurality of conductive bumps 211.

In other embodiments, the electronic element 21 may directly contact the circuit layer of the carrier structure 20.

It should be understood that there are many ways for the electronic element 21 to be electrically connected to the carrier structure 20, and the required type and quantity of the electronic element 21 can be connected onto the carrier structure 20, and the present disclosure is not limited to the above.

In one embodiment, the first side 20a of the carrier structure 20 may be defined with a chip mounting area A and a peripheral area B, so that the electronic element 21 is disposed on the chip mounting area A on the first side 20a of the carrier structure 20.

As shown in FIG. 2A, a first barrier body 22 is formed around the electronic element 21 to surround side surfaces 21c of the electronic element 21, and the first barrier body 22 can also be further formed around the underfill 212 to surround side surfaces of the underfill 212. In an embodiment, the first barrier body 22 may be made of insulating material (such as insulating colloid). Further, at the stage shown in FIG. 2A, the first barrier body 22 is heated and cured.

As shown in FIG. 2B, a second barrier body 23 is formed on the cured first barrier body 22 and is formed with an opening 231 for exposing the electronic element 21; meanwhile, an adhesive layer 26 can also be formed on the carrier structure 20. At this stage, the second barrier body 23 has not yet cured and is in a semi-molten state.

When the second barrier body 23 is not yet cured and is in a semi-molten state, a heat dissipation structure 25 is disposed on the first side 20a of the carrier structure 20. The heat dissipation structure 25 can be made of heat dissipation material (such as metal material), and the heat dissipation structure 25 includes a heat dissipation member 251 with a hole 253 and at least one (such as a plurality of) support member 252.

In an embodiment, the heat dissipation member 251 of the heat dissipation structure 25 can be bonded onto the second barrier body 23 in a semi-molten state. For example, the second barrier body 23 is first formed on the first barrier body 22 in a manner of dispensing glue. The heat dissipation member 251 of the heat dissipation structure 25 is adhered onto the second barrier body 23 before the second barrier body 23 is cured. In addition, the hole 253 on the heat dissipation member 251 is disposed in a region corresponding to the electronic element 21 and is in communication with the opening 231 of the second barrier body 23.

In an embodiment, the support member 252 of the heat dissipation structure 25 can extend downward from an edge of the heat dissipation member 251 and can be bonded to the carrier structure 20 via the adhesive layer 26. For example, the adhesive layer 26 is formed on the peripheral area B of the first side 20a of the carrier structure 20 in a manner of dispensing glue, and then the support member 252 of the heat dissipation structure 25 is adhered onto the adhesive layer 26, thereby fixing the heat dissipation structure 25 onto the carrier structure 20.

In the stage shown in FIG. 2B, after the heat dissipation structure 25 is disposed, the second barrier body 23 and the adhesive layer 26 are heated and cured. Even if the second barrier body 23 generates gas during heating, the gas can be discharged to the outside via the hole 253 of the heat dissipation structure 25.

In an embodiment, the second barrier body 23 can be made of insulating material (such as insulating colloid), and the first barrier body 22 and the second barrier body 23 can be made of the same material, but with an interface L between the first barrier body 22 and the second barrier body 23, wherein the interface L is caused by the different curing times of the first barrier body 22 and the second barrier body 23. Specifically, the first barrier body 22 has been cured before the second barrier body 23 is formed. Therefore, even if the second barrier body 23 is subsequently formed with the same material as the first barrier body 22, there will be the interface L between the first barrier body 22 and the second barrier body 23. By curing the first barrier body 22 before being covered by the heat dissipation structure 25, the gas generated by heating the first barrier body 22 can be directly dissipated; and after covering with the heat dissipation structure 25, the gas generated by heating the second barrier body 23 located near the hole 253 can be easily discharged to the outside of the heat dissipation structure 25 via the hole 253. Further, the present disclosure is not limited to the above; and in other embodiments, the first barrier body 22 and the second barrier body 23 can also be made of different materials.

As shown in FIG. 2C-1, a material forming a thermal conductive layer 24 is injected between the heat dissipation structure 25 and the electronic element 21 via the hole 253 of the heat dissipation structure 25.

In an embodiment, the thermal conductive layer 24 may be a thermal interface material (TIM) layer composed of liquid thermal conductive material. For example, the thermal conductive layer 24 can be made of liquid thermal conductive material such as tin, gallium, indium, etc., or a combination thereof, and the thermal conductive layer 24 has high thermal conductivity (e.g., 86 W/mK).

Furthermore, in an embodiment, the first barrier body 22 can be formed slightly higher than the electronic element 21, so that the first barrier body 22 and the second barrier body 23 together surround the thermal conductive layer 24 on the electronic element 21, such that the first barrier body 22 and the second barrier body 23 jointly prevent the thermal conductive layer 24 from overflowing onto the side surfaces 21c of the electronic element 21 and the carrier structure 20 and causing adverse effects (such as electrical short circuit). However, the present disclosure is not limited to the above, the first barrier body 22 can also be of the same height as the electronic element 21, or the first barrier body 22 can be lower than the electronic element 21, and the thermal conductive layer 24 on the electronic element 21 is blocked or surrounded merely by the second barrier body 23, such that the second barrier body 23 prevents the thermal conductive layer 24 from overflowing onto the side surfaces 21c of the electronic element 21 and the carrier structure 20 and causing adverse effects (such as electrical short circuit).

Further, please also refer to FIG. 2C-2, which is a schematic partial top view of FIG. 2C-1. The second barrier body 23 is disposed according to a shape of the first barrier body 22 surrounding the electronic element 21, and the second barrier body 23 may be formed approximately in a ring shape, an O-shape, a square shape, etc. Furthermore, the thermal conductive layer 24 is formed on the electronic element 21 (such as the inactive surface 21b) exposed from the opening 231 of the second barrier body 23, and the thermal conductive layer 24 is surrounded by the second barrier body 23. With this design, the thermal conductive layer 24 will not overflow outside the opening 231 of the second barrier body 23. In other words, the thermal conductive layer 24 can be limited in the chip mounting area A (i.e., the region above the electronic element 21). In addition, the adhesive layer 26 can be formed on and around the carrier structure 20, so that the support member 252 of the heat dissipation structure 25 can be well connected onto the carrier structure 20 via the adhesive layer 26.

As shown in FIG. 2D, a covering layer 27 is formed above the hole 253 of the heat dissipation structure 25 to prevent the thermal conductive layer 24 from overflowing.

In an embodiment, the covering layer 27 is formed by using a metal layer, but the present disclosure is not limited to as such, and the covering layer 27 may be also formed by other methods or other materials. Furthermore, slightly more material of the thermal conductive layer 24 may be injected, so that the thermal conductive layer 24 fills up the space between the heat dissipation structure 25 and the electronic element 21 and fills a part of the hole 253. However, the present disclosure is not limited to the above. The thermal conductive layer 24 may not fill a part of the hole 253, and the hole 253 may be sealed merely by the covering layer 27. Alternatively, the thermal conductive layer 24 may fill up the hole 253, and the covering layer 27 may cover above the thermal conductive layer 24 and the heat dissipation member 251.

Then, a plurality of metal pillars such as copper pillars, metal bumps covered with insulating blocks, solder balls, solder balls with copper (Cu) core balls, or conductive elements (not shown) of other conductive structures can be disposed on the second side 20b of the carrier structure 20 to obtain the electronic package 2 of the present disclosure. Subsequently, the electronic package 2 can be connected to an electronic device such as a circuit board (not shown) via a plurality of conductive elements.

The present disclosure further provides an electronic package 2, which includes: a carrier structure 20; an electronic element 21 disposed on the carrier structure 20; a first barrier body 22 disposed on the carrier structure 20 and surrounding side surfaces 21c of the electronic element 21; a second barrier body 23 disposed on the first barrier body 22 and formed with an opening 231 exposing the electronic element 21; a thermal conductive layer 24 formed on the electronic element 21 exposed from the opening 231 of the second barrier body 23, wherein the thermal conductive layer 24 on the electronic element 21 is surrounded by the second barrier body 23; and a heat dissipation structure 25 disposed on the second barrier body 23 and the thermal conductive layer 24, wherein the thermal conductive layer 24 is between the electronic element 21 and the heat dissipation structure 25, and the heat dissipation structure 25 is formed with a hole 253 in a region corresponding to the electronic element 21.

In one embodiment, the first barrier body 22 and the second barrier body 23 have an interface L therebetween.

In one embodiment, the first barrier body 22 is higher than the electronic element 21, and the first barrier body 22 and the second barrier body 23 together surround the thermal conductive layer 24 on the electronic element 21.

In one embodiment, the first barrier body 22 and the second barrier body 23 are made of the same material.

In one embodiment, the hole 253 is disposed with a covering layer 27 thereon.

In one embodiment, the hole 253 is filled by the thermal conductive layer 24 and the covering layer 27.

In one embodiment, the thermal conductive layer 24 is limited to a region above the electronic element 21.

In one embodiment, the thermal conductive layer 24 is made of liquid thermal conductive material.

In view of the above, in the electronic package and manufacturing method thereof of the present disclosure, the heat dissipation structure is formed with a hole thereon, so that the gas in the heat dissipation structure can be discharged via the hole to prevent gas from remaining in the thermal conductive layer and affecting the heat dissipation effect.

Furthermore, since the present disclosure disposes the first barrier body and the second barrier body respectively in two steps, and the first barrier body is first cured before covering the heat dissipation structure, when heating is performed after being covered with the heat dissipation structure, the gas generated by the second barrier body near the hole can be easily discharged from the hole of the heat dissipation structure without being accumulated in the heat dissipation structure.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. An electronic package, comprising:
a carrier structure;
an electronic element disposed on the carrier structure;
a first barrier body disposed on the carrier structure and surrounding side surfaces of the electronic element;
a second barrier body disposed on the first barrier body and formed with an opening exposing the electronic element;
a thermal conductive layer formed on the electronic element exposed from the opening of the second barrier body, wherein the thermal conductive layer is surrounded by the second barrier body; and
a heat dissipation structure disposed on the second barrier body and the thermal conductive layer, wherein the thermal conductive layer is positioned between the electronic element and the heat dissipation structure, and the heat dissipation structure has a hole in communication with the opening.

2. The electronic package of claim 1, wherein the first barrier body and the second barrier body have an interface therebetween.

3. The electronic package of claim 1, wherein the first barrier body is higher than the electronic element, and the first barrier body and the second barrier body together surround the thermal conductive layer on the electronic element.

4. The electronic package of claim 1, wherein the first barrier body and the second barrier body are made of same material.

5. The electronic package of claim 1, wherein the hole is disposed with a covering layer thereon.

6. The electronic package of claim 1, wherein the thermal conductive layer is made of a liquid thermal conductive material.

7. A method of manufacturing an electronic package, comprising:
disposing an electronic element on a carrier structure;
disposing a first barrier body on the carrier structure, wherein the first barrier body surrounds side surfaces of the electronic element;
disposing a second barrier body on the first barrier body, wherein the second barrier body is formed with an opening exposing the electronic element;
disposing a heat dissipation structure with a hole on the second barrier body, wherein the hole is in communication with the opening of the second barrier body; and
forming a thermal conductive layer on the electronic element exposed from the opening of the second barrier body via the hole, wherein the thermal conductive layer is surrounded by the second barrier body.

8. The method of claim 7, wherein the first barrier body is heated and cured before disposing the second barrier body.

9. The method of claim 7, wherein the heat dissipation structure is disposed on the second barrier body when the second barrier body is in an uncured state.

10. The method of claim 7, wherein the first barrier body and the second barrier body have an interface therebetween.

11. The method of claim 7, wherein the first barrier body is higher than the electronic element, and the first barrier body and the second barrier body together surround the thermal conductive layer on the electronic element.

12. The method of claim 7, wherein the first barrier body and the second barrier body are made of same material.

13. The method of claim 7, further comprising forming a covering layer on the hole.

14. The method of claim 7, wherein the thermal conductive layer is made of a liquid thermal conductive material.
